(19) United States
(12) Patent Application Publication
(10) Pub. No.: US 2009/0045518 A1
(43) Pub. Date: Feb. 19, 2009

(54) SEMICONDUCTOR DEVICE AND METHOD FOR FABRICATING THE SAME

(75) Inventor: Sang-Hoon CHO, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Ichon-shi (KR)

(21) Appl. No.: 12/165,204

(22) Filed: Jun. 30, 2008

(30) Foreign Application Priority Data
Aug. 14, 2007 (KR) 10-2007-0081605

(51) Int. Cl. H01L 23/52; H01L 21/4763

(52) U.S. Cl. 257/770; 438/624; 257/E23.141; 257/E21.495

(57) ABSTRACT

A method for fabricating a semiconductor device includes forming a plurality of conductive patterns over a substrate, forming a spin on dielectric (SOD) layer filling a portion of space between the conductive patterns, and forming an insulation pattern filling the remaining space over the SOD layer, wherein the stacked structure of the SOD layer and the insulation pattern forms a first interlayer dielectric layer.

### CROSS-REFERENCE TO RELATED APPLICATIONS

The present invention claims priority of Korean patent application number 10-2007-0081605, filed on Aug. 14, 2007, which is incorporated by reference in its entirety.

### BACKGROUND OF THE INVENTION

The present invention relates to a method for fabricating a semiconductor device, and more particularly, to a semiconductor device having an interlayer dielectric layer and a method for fabricating the same.

As a semiconductor device becomes highly integrated, an interval between patterns becomes narrower. Therefore, insulation between the patterns becomes a critical issue.

According to a typical method, a bit line and a storage node are insulated from each other by depositing an oxide layer as an interlayer dielectric layer after forming the bit line. However, as a semiconductor device shrinks in size, space between bit lines is drastically decreased. Therefore, it is difficult to gap-fill the interlayer dielectric layer.

To resolve the above limitation, spin on dielectric (SOD) having an excellent gap-fill characteristic is used as an interlayer dielectric layer in the fabrication of sub-50-nm semiconductor devices.

FIGS. 1A to 1D illustrate a method for fabricating a typical semiconductor device. In FIG. 1A, a bit line 11 having a stacked structure of a bit line conductive layer 11A and a bit line hard mask 11B is formed over a substrate 10 having a peripheral region and a cell region.

Referring to FIG. 1B, a first interlayer dielectric layer 12 is formed over a resulting structure until it sufficiently fills a space between the bit lines 11. The first interlayer dielectric layer 12 may be formed of a SOD layer. A chemical mechanical polishing (CMP) process is performed on the first interlayer dielectric layer 12 until the bit line hard mask 11B is exposed. If the SOD layer is used as the interlayer dielectric layer, excellent gap-fill characteristic can be obtained.

A capacitor (not shown) is formed on the cell region in a known method. Since this is not related to the technical problem, its description will be omitted.

Referring to FIG. 1C, a second interlayer dielectric layer 13 is formed over a resulting structure including the capacitor. A metal contact hole 14 is formed by selectively etching the second interlayer dielectric layer 13 and the bit line hard mask 11B until the bit line conductive layer 11A of the peripheral region is exposed.

Referring to FIG. 1D, a pre-cleaning process is performed before filling the metal contact hole 14 with a metal. Although not illustrated, the metal contact hole 14 is filled with a metal to form a metal contact.

The typical method for fabricating the semiconductor device, however, has the following limitations. If the SOD layer is used as the first interlayer dielectric layer 12 for insulation of the bit lines 11, the gap-fill characteristic is improved. However, an annealing process is necessarily performed on the SOD layer due to characteristics of the SOD layer. Such an annealing process on the SOD layer causes the bending of the bit lines 11.

Additionally, if the metal contact hole 14 is misaligned, the first interlayer dielectric layer 12 formed of the SOD layer is partially exposed by the metal contact hole 14. If the SOD layer is partially exposed by the metal contact hole 14, the exposed portion of the SOD layer may be lost during a subsequent pre-cleaning process by a wet attack, which is indicated by a dotted circle in FIG. 1D. The loss of the SOD layer causes a filling failure when forming a metal contact in a subsequent process, which is indicated by a dotted circle in FIG. 2.

### SUMMARY OF THE INVENTION

Embodiments of the present invention relate to a semiconductor device, which is capable of improving the gap-fill characteristic of an interlayer dielectric layer (e.g., for insulation of conductive patterns such as bit lines) and preventing defects of devices by using a dual interlayer dielectric layer, and a method for fabricating the semiconductor device.

In accordance with an aspect of the present invention, there is provided a method for fabricating a semiconductor device. The method includes forming a plurality of conductive patterns over a substrate, forming a spin on dielectric (SOD) layer filling a portion of space between the conductive patterns, and forming an insulation pattern filling the remaining space over the SOD layer, wherein the stacked structure of the SOD layer and the insulation pattern forms a first interlayer dielectric layer.

In accordance with another aspect of the present invention, there is provided a semiconductor device. The semiconductor device includes a substrate, a plurality of conductive patterns formed over the substrate, a spin on dielectric (SOD) layer filling a portion of space between the conductive patterns, and an insulation pattern filling the remaining space over the SOD layer, wherein the stacked structure of the SOD layer and the insulation pattern forms a first interlayer dielectric layer.

### BRIEF DESCRIPTION OF THE DRAWINGS

FIGS. 1A to 1D illustrate a typical method for fabricating a semiconductor device.

FIG. 2 illustrates micrographic views for explaining limitations that occur in the fabrication of a typical semiconductor device.

FIGS. 3A to 3G illustrate a method for fabricating a semiconductor device in accordance with an embodiment of the present invention.

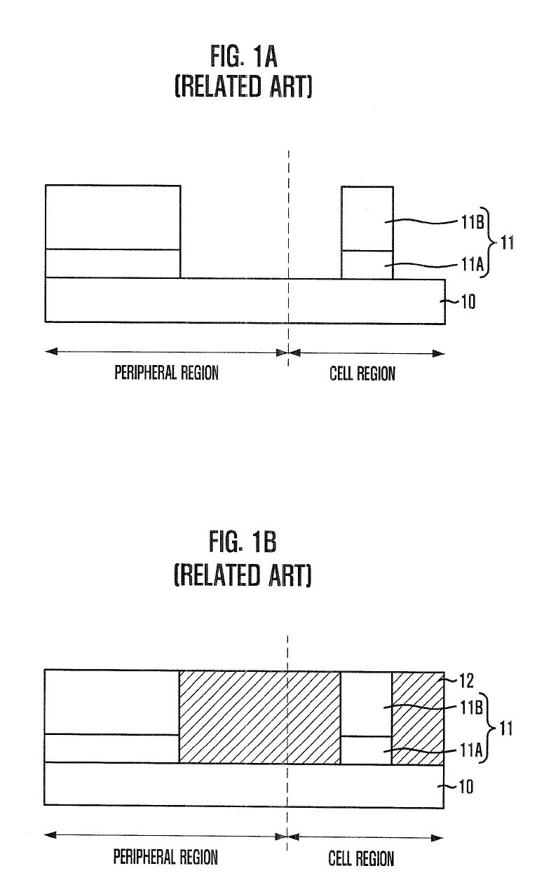

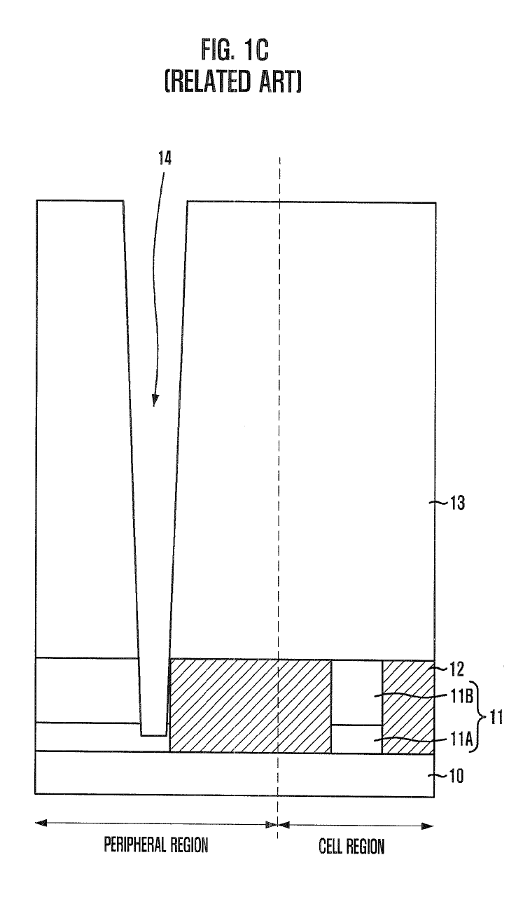

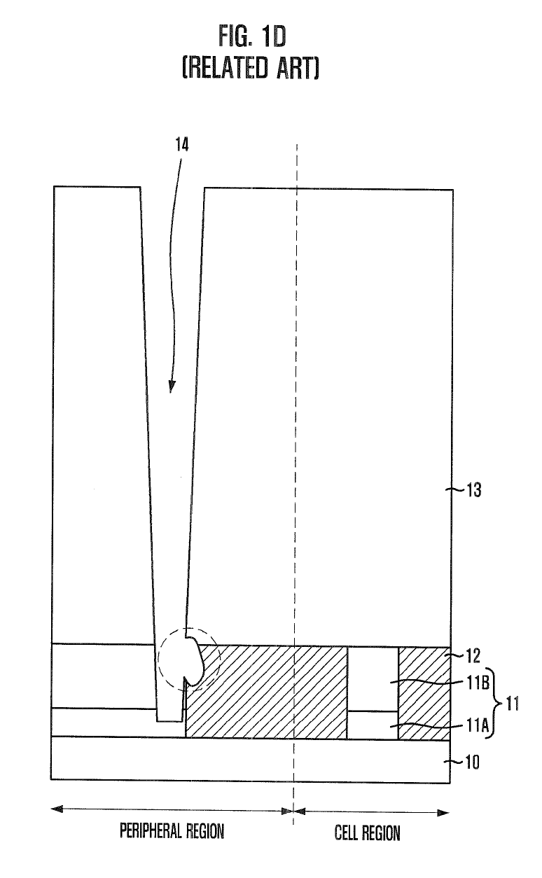

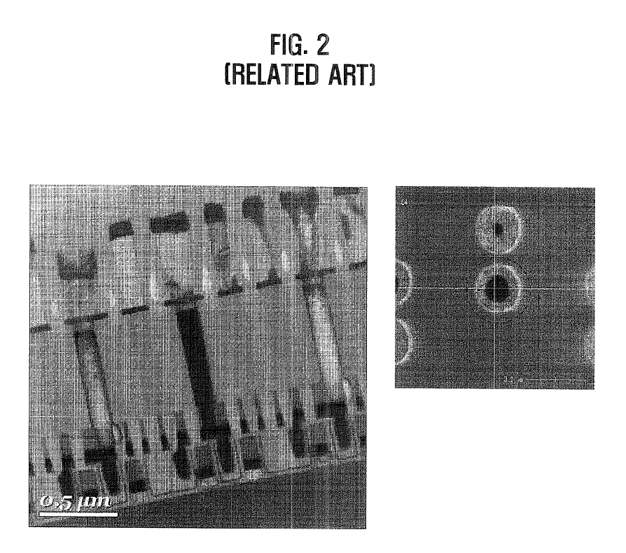

### DESCRIPTION OF SPECIFIC EMBODIMENTS

Hereinafter, a semiconductor device and a method for fabricating the same in accordance with the present invention will be described in detail with reference to the accompanying drawings.

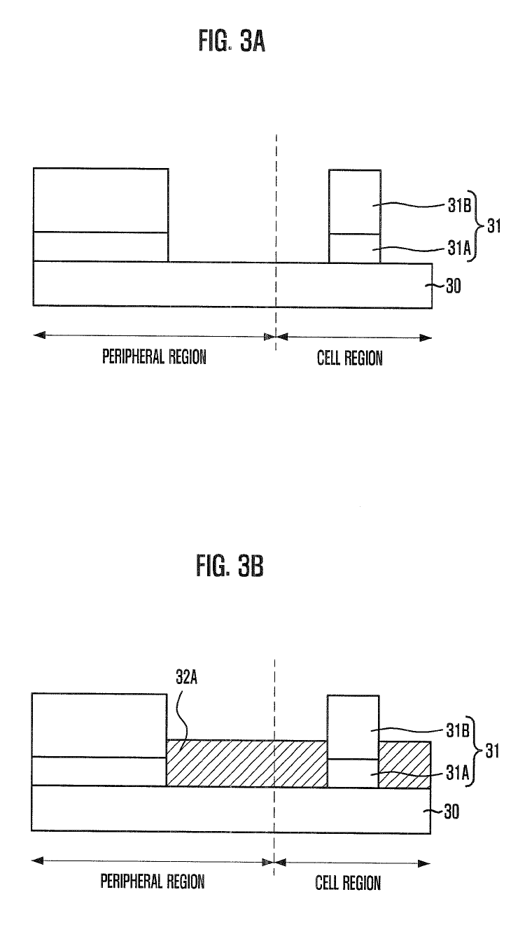

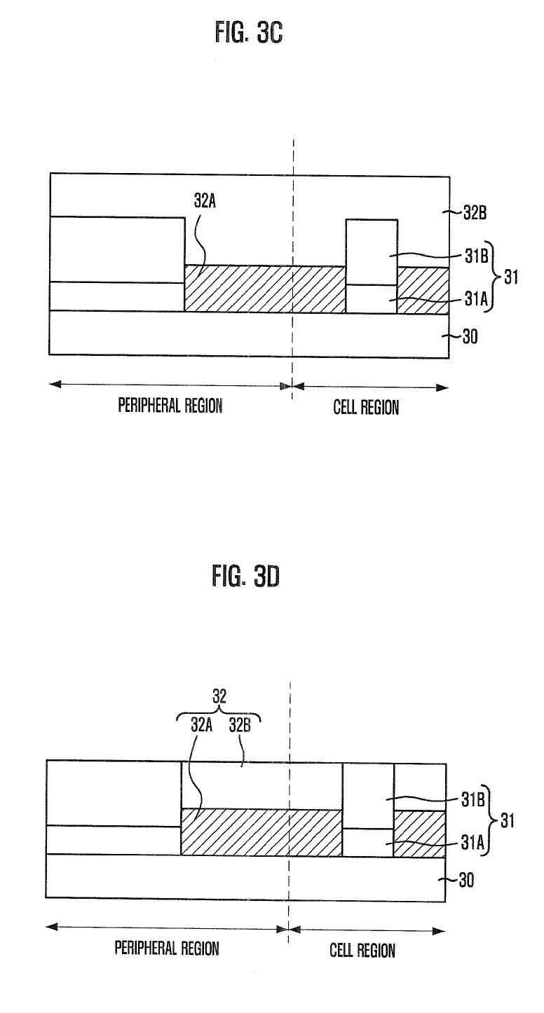

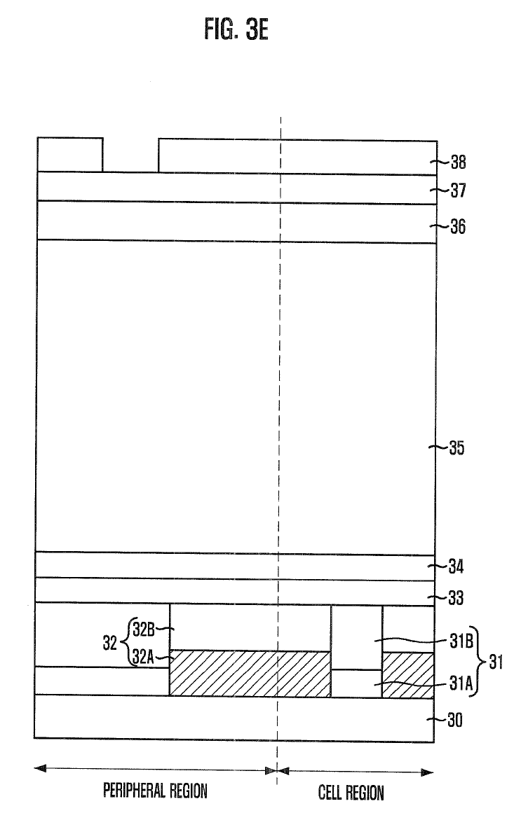

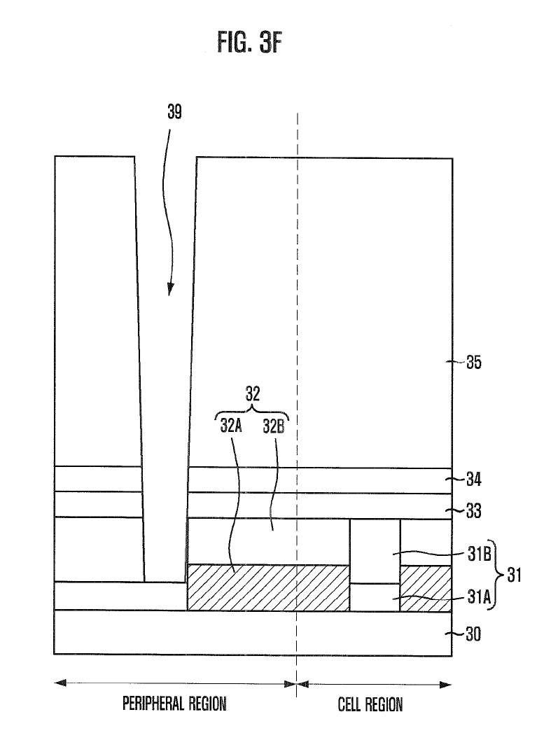

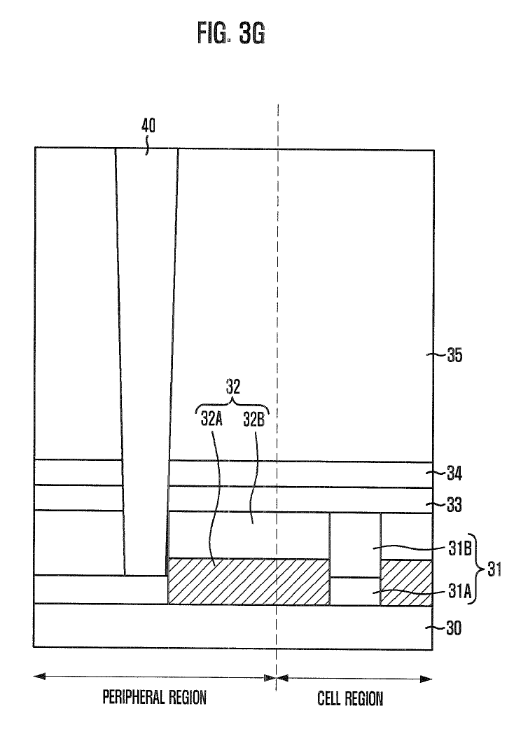

FIGS. 3A to 3G illustrate a method for fabricating a semiconductor device in accordance with an embodiment of the present invention. In FIG. 3A, bit lines 31 are formed over a substrate 30 having a peripheral region and a cell region. The bit line 31 has a stacked structure of a bit line conductive layer 31A and a bit line hard mask 31B.

Referring to FIG. 3B, an SOD layer 32A is formed to partially fill a space between the bit lines 31. A thickness of the SOD layer 32A may be approximately one third of a thickness of a subsequent bit line hard mask 31B.

Referring to FIG. 3C, an insulation layer 32B is formed over a resulting structure including the SOD layer 32A. The insulation layer 32B may include an oxide layer having a relatively low wet etch rate, for example, a high density plasmas chemical vapor deposition (HDP CVD) oxide layer or a high aspect ratio process (HARP) oxide layer.

Referring to FIG. 3D, a planarization process (for example, a chemical mechanical polishing (CMP) process) is performed on the insulation layer 32B, until the bit line hard mask 31B is exposed, to form an insulation pattern filling the remaining space between the bit lines 31.

Through the processes of FIGS. 3B to 3D, a first interlayer dielectric layer 32 having a stacked structure of the SOD layer 32A and an insulation pattern 32B is formed in the space between the bit lines 31. The first interlayer dielectric layer 32 having the stacked structure of the SOD layer 32A and insulation pattern 32B has the following advantages.

An aspect ratio of the space between the bit lines 31 can be reduced because the space between the bit lines 31 is partially filled with the SOD layer 32A having the excellent gap-fill characteristic. Therefore, the filling of the insulation pattern 32B is facilitated. Additionally, the annealing process on the SOD layer 32A can be omitted, which was needed when forming the interlayer dielectric layer consisting of the SOD layer. Thus, the fabricating processes may be simplified and the bending of the bit line 31 can be prevented. Furthermore, the filling failure can be prevented in forming a subsequent metal contact, which will be described below in more detail.

Referring to FIG. 3E, a buffer oxide layer 33 is formed over a resulting structure. An etch stop layer 34 (e.g., nitride layer) is further formed above the buffer oxide layer 33.

Although not illustrated, a capacitor (not shown) is formed in the cell region by a known method.

A second interlayer dielectric layer 35 is formed on a resulting structure including the capacitor, and an amorphous carbon layer 36 and a silicon oxynitride (SiON) layer 37 serving as a hard mask are sequentially formed on the second interlayer dielectric layer 35.

In order to form a metal contact, a photoresist pattern 38 is formed on the silicon oxynitride (SiON) layer 37. An anti-reflective coating (not shown) may be further formed below the photoresist pattern 38 in order to prevent reflection of light during an exposure process.

Referring to FIG. 3F, the silicon oxynitride (SiON) layer 37 and the amorphous carbon layer 36 are sequentially etched using the photoresist pattern 38 as an etch barrier, and the second interlayer dielectric layer 35, the etch stop layer 34, the buffer oxide layer 33, and the bit line hard mask 31B are sequentially etched until the bit line conductive layer 31A is exposed. As a result, a metal contact hole 39 is formed which exposes the bit line conductive layer 31A of the peripheral region.

Referring to FIG. 3G, before filling the metal contact hole 39 with a metal, a pre-cleansing process is performed. At this point, even if the metal contact hole 39 is misaligned, the bit line hard mask layer 31B instead of the SOD layer 32A is exposed because the first interlayer dielectric layer 32 has a dual structure. As mentioned above, since the insulation pattern 32B includes an oxide layer having a relatively low wet etch rate, the loss of the insulation pattern 32B is minimized even though a pre-cleansing process is performed.

Therefore, it is possible to minimize the filling failure when the metal contact 40 is formed by filling the metal contact hole 39 with a metal, for example, tungsten.

In accordance with the embodiments of the present invention, the semiconductor device is capable of improving the gap-fill characteristic of an interlayer dielectric layer and preventing defects of devices by using the dual interlayer dielectric layer when forming the interlayer dielectric layer for insulation of conductive patterns such as bit lines.

While the present invention has been described with respect to the specific embodiments, the above embodiments of the present invention are illustrative and not limitative. It will be apparent to those skilled in the art that various changes and modifications may be made without departing from the spirit and scope of the invention as defined in the following claims.

What is claimed is:

1. A method for fabricating a semiconductor device, the method comprising:
forming a plurality of conductive patterns over a substrate, the conductive patterns defining space therebetween, the space having an upper region and a lower region;
forming a spin on dielectric (SOD) layer filling the lower region of the space defined between the conductive patterns; and
forming an insulation pattern over the SOD layer, the insulation pattern filling the upper region of the space,
wherein the SOD layer and the insulation pattern define a first interlayer dielectric layer.

2. The method of claim 1, wherein the space exposes the substrate and the SOD layer contacts the substrate.

3. The method of claim 2, wherein the insulation pattern comprises an oxide layer having a low wet etch rate, where the insulation pattern comprises a high density plasma chemical vapor deposition (HDP CVD) oxide layer or a high aspect ratio process (HARP) oxide layer.

4. The method of claim 1, wherein the conductive pattern is a bit line where a bit line conductive layer and a bit line hard mask are stacked.

5. The method of claim 4, wherein a thickness of the SOD layer is approximately one third of a thickness of the bit line hard mask.

6. The method of claim 4, wherein forming of the insulation pattern comprises:
forming an insulation layer over the insulation pattern and the conductive patterns; and
performing a chemical mechanical polishing (CMP) process on the insulation layer until the bit line hard mask is exposed.

7. The method of claim 4, further comprising, after forming of the insulation pattern:
forming a second interlayer dielectric layer over the insulation pattern and the conductive patterns;
selectively etching the second interlayer dielectric layer and the bit line hard mask to form a metal contact hole exposing the bit line conductive layer;
performing a pre-cleansing process; and
filling the metal contact hole to form a metal contact.

8. The method of claim 7, wherein the substrate has a peripheral region and a cell region, and the metal contact hole is formed in the peripheral region.

9. The method of claim 7, wherein the metal contact comprises tungsten.

10. A semiconductor device, comprises:
a substrate;
a plurality of conductive patterns formed over the substrate;
a spin on dielectric (SOD) layer filling a lower portion of space between the conductive patterns; and
an insulation pattern provided over the SOD layer, the insulation pattern filling an upper portion of the space,
wherein the SOD layer and the insulation pattern define a first interlayer dielectric layer.

11. The semiconductor device of claim 10, wherein the insulation pattern comprises an oxide layer having a low wet etch rate.

12. The semiconductor device of claim 11, wherein the insulation pattern comprises a high density plasmas chemical vapor deposition (HDP CVD) oxide layer or a high aspect ratio process (HARP) oxide layer.

13. The semiconductor device of claim 10, wherein the conductive pattern is a bit line including a bit line conductive layer and a bit line hard mask.

14. The semiconductor device of claim 13, wherein a thickness of the SOD layer is approximately one third of a thickness of the bit line hard mask.

15. The semiconductor device of claim 13, further comprising:
a second interlayer dielectric layer formed over the bit line and the first interlayer dielectric layer;
a contact hole extending through the second interlayer dielectric layer and the bit line hard mask to expose the bit line conductive layer; and
a contact plug filling the contact hole.

16. The semiconductor device of claim 15, wherein the substrate has a peripheral region and a cell region, and the contact hole is formed in the peripheral region.

17. The semiconductor device of claim 15, wherein the contact plug comprises tungsten.
